(19) United States
(12) Patent Application Publication
(10) Pub. No.: US 2024/0381739 A1
(43) Pub. Date: Nov. 14, 2024

(54) DISPLAY DEVICE AND METHOD OF MANUFACTURING THE SAME

(71) Applicant: Samsung Display Co., LTD., Yongin-si (KR)

(72) Inventors: HYUNEOK SHIN, Yongin-si (KR); JOONYONG PARK, Yongin-si (KR); BYUNG SOO SO, Yongin-si (KR); YUNJONG YEO, Yongin-si (KR); YUNG BIN CHUNG, Yongin-si (KR)

(21) Appl. No.: 18/631,184

(22) Filed: Apr. 10, 2024

(30) Foreign Application Priority Data
May 12, 2023 (KR) 10-2023-0061955

(51) Int. Cl. H10K 59/82; H10K 59/12; H10K 102/00

(52) U.S. Cl. CPC H10K 59/82; H10K 59/1201; H10K 2102/351

(57) ABSTRACT

A display device includes a base layer, a circuit layer disposed on the base layer, and a light emitting element disposed on the circuit layer. The circuit layer includes a first insulating layer disposed on the base layer, provided with a first contact hole defined therethrough, and including silicon nitride, a second insulating layer disposed on the first insulating layer, provided with a second contact hole defined therethrough to correspond to the first contact hole, and including silicon oxide, and a connection electrode disposed on the second insulating layer. The connection electrode includes first and second electrode portions disposed in the first and second contact holes, respectively, a minimum value of a width of the first contact hole is in a range of about 0.5 micrometers to about 2 micrometers, and a portion of the second electrode portion is in contact with an upper surface of the first insulating layer.

This application claims priority to Korean Patent Application No. 10-2023-0061955, filed on May 12, 2023, and all the benefits accruing therefrom under 35 U.S.C. § 119, the content of which in its entirety is herein incorporated by reference.

### BACKGROUND

### 1. Field

The disclosure relates to a display device and a method of manufacturing the display device. More particularly, the disclosure relates to a display device having characteristics such as high resolution, high speed drive, etc., and a method of manufacturing the display device.

### 2. Description of the Related Art

A display device typically includes pixels and a driving circuit, e.g., a scan driving circuit, a data driving circuit, etc., to control the pixels. Each of the pixels may include a display element and a pixel driving circuit for controlling the display element. he pixel driving circuit may include a plurality of transistors connected to each other.

As the size and resolution of the display device increases, the number of signal lines and connection electrodes, which connect the display element and the transistors included in the pixels, also increases, and a degree of integration of the pixel driving circuit increases.

### SUMMARY

The disclosure provides a display device with a high-resolution and high-speed drive by implementing a highly integrated pixel circuit.

The disclosure provides a method of manufacturing the display device.

Embodiments of the invention provide a display device including a base layer, a circuit layer disposed on the base layer, and a light emitting element disposed on the circuit layer. In such embodiments, the circuit layer includes a first insulating layer disposed on the base layer, provided with a first contact hole defined therethrough, and including silicon nitride, a second insulating layer disposed on the first insulating layer, provided with a second contact hole defined therethrough to correspond to the first contact hole, and including silicon oxide, and a connection electrode disposed on the second insulating layer, where a portion of the connection electrode is disposed in the first and second contact holes.

In such embodiments, the connection electrode includes a first electrode portion disposed in the first contact hole and a second electrode portion disposed in the second contact hole, a minimum value of a width in one direction of the first contact hole is equal to or greater than about 0.5 micrometers and equal to or less than about 2 micrometers, and a portion of the second electrode portion is in contact with an upper surface of the first insulating layer.

In an embodiment, a maximum value of the width in the one direction of the first contact hole may be less than a minimum value of a width in the one direction of the second contact hole.

In an embodiment, the first electrode portion may be in contact with a first side surface of the first insulating layer, the second electrode portion may be in contact with a second side surface of the second insulating layer, and the first side surface and the second side surface may be arranged in a staggered form.

In an embodiment, the first contact hole may include a lower portion adjacent to the base layer and having a first-first slope and an upper portion adjacent to the second insulating layer and having a first-second slope, and the first-first slope may be greater than the first-second slope.

In an embodiment, The first-first slope may be in an angle equal to or greater than about 85 degrees and equal to or less than about 95 degrees with respect to the upper surface of the first insulating layer, and the first-second slope may be in an angle equal to or greater than about 60 degrees and equal to or less than about 80 degrees with respect to the upper surface of the first insulating layer.

In an embodiment, a first-first width in the one direction of the lower portion may be less than a first-second width in the one direction of the upper portion.

In an embodiment, the first-first width in the one direction of the lower portion may be equal to or greater than about 1 micrometer and equal to or less than about 1.8 micrometers.

In an embodiment, a width in the one direction of the second contact hole may be uniform in a thickness direction, and a difference between the first-second width and the width of the second contact hole in the one direction may be equal to or greater than about 0.2 micrometers.

In an embodiment, a ratio of the difference between the first-second width and the width of the second contact hole to the first-first width in the one direction may be equal to or greater than about 0.2.

In an embodiment, the circuit layer may further include a first organic layer disposed on the second insulating layer and provided with a first upper contact hole defined therethrough and an upper connection electrode disposed in the first upper contact hole and electrically connected to the connection electrode.

In an embodiment, the light emitting element may include a first electrode, a light emitting layer disposed on the first electrode, and a second electrode disposed on the light emitting layer, the circuit layer may further include a second organic layer disposed on the first organic layer and provided with a second upper contact hole defined therethrough, and a portion of the first electrode may be disposed in the second upper contact hole and electrically connected to the upper connection electrode.

In an embodiment, the circuit layer further may include a transistor disposed on the base layer, the transistor includes a semiconductor pattern disposed on the base layer and a gate electrode disposed on the first insulating layer, at least a portion of an upper surface of the semiconductor pattern may be exposed through the first contact hole, and the connection electrode may be electrically connected to the semiconductor pattern via the first and second contact holes.

In an embodiment, the circuit layer may further include a lower insulating layer disposed on the base layer, the semiconductor pattern is disposed on the lower insulating layer, and the lower insulating layer may include silicon oxide, silicon nitride, or silicon oxynitride.

Embodiments of the invention provide a display device including a base layer, a circuit layer disposed on the base layer, and a light emitting element disposed on the circuit layer. In such embodiments, the circuit layer includes a first insulating layer disposed on the base layer, provided with a first contact hole defined therethrough, and including silicon nitride, a second insulating layer disposed on the first insulating layer, provided with a second contact hole defined therethrough to correspond to the first contact hole, and including silicon oxide, and a connection electrode disposed on the second insulating layer. In such embodiments, the first contact hole includes a lower portion adjacent to the base layer and having a first-first slope and an upper portion adjacent to the second insulating layer and having a first-second slope, the first-first slope is in an angle equal to or greater than about 85 degrees and equal to or less than about 95 degrees with respect to an upper surface of the first insulating layer, and the first-second slope is in an angle equal to or greater than about 60 degrees and equal to or less than about 80 degrees with respect to the upper surface of the first insulating layer.

Embodiments of the invention provide a method of manufacturing a display device. In such embodiments, the method includes providing an electrode layer, a first insulating layer including silicon nitride and disposed on the electrode layer, and a second insulating layer disposed on the first insulating layer and including silicon nitride, forming a contact hole through the first insulating layer and the second insulating layer, and providing a connection electrode in the contact hole. In such embodiments, the forming the contact hole includes anisotropically etching a portion of the first insulating layer and a portion of the second insulating layer, isotropically etching a portion of the second insulating layer to expose an upper surface of the first insulating layer, and anisotropically etching a portion of the first insulating layer to expose an upper surface of the electrode layer.

In an embodiment, the forming the contact hole may further include forming a photoresist pattern on the second insulating layer before the anisotropically etching the portion of the first insulating layer and the portion of the second insulating layer.

In an embodiment, the anisotropically etching the portion of the first insulating layer and the portion of the second insulating layer may include forming a first preliminary contact hole in the first insulating layer and forming a second preliminary contact hole through the second insulating layer, and the first preliminary contact hole and the second preliminary contact hole may have substantially a same slope as each other.

In an embodiment, the first preliminary contact hole may be formed by etching only the portion of the first insulating layer in a thickness direction.

In an embodiment, the first preliminary contact hole and the second preliminary contact hole may have substantially a same width as each other.

In an embodiment, the isotropically etching the portion of the second insulating layer may include forming an undercut in a lower portion of the photoresist pattern.

According to embodiments of the invention, even when the number of the signal lines and the degree of integration of the circuit increase, it is possible to configure a pixel layout within a limited pixel pitch, and thus, the display device having characteristics, such as, high-resolution and high-speed drive, are provided.

### BRIEF DESCRIPTION OF THE DRAWINGS

The above and other features of embodiments of the disclosure will become readily apparent by reference to the following detailed description when considered in conjunction with the accompanying drawings, in which:

FIG. 1A is a perspective view of a display device according to an embodiment of the disclosure;

FIG. 1B is an exploded perspective view of a display device according to an embodiment of the disclosure;

FIGS. 1C and 1D are cross-sectional views of display modules according to embodiments of the disclosure;

FIG. 2A is a perspective view of a display device according to an embodiment of the disclosure;

FIG. 2B is an exploded perspective view of a display device according to an embodiment of the disclosure;

FIG. 3 is a cross-sectional view of a display panel according to an embodiment of the disclosure;

FIG. 4 is a plan view of a display panel according to an embodiment of the disclosure;

FIG. 5 is an equivalent circuit diagram of a pixel according to an embodiment of the disclosure;

FIG. 6 is a cross-sectional view of a pixel according to an embodiment of the disclosure;

FIGS. 7A and 7B are cross-sectional views of some components of a display device according to an embodiment of the disclosure;

FIGS. 8A and 8B are flowcharts illustrating a method of manufacturing a display device according to an embodiment of the disclosure; and

FIGS. 9A to 9E are cross-sectional views illustrating a method of manufacturing a display device according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. “Or” means “and/or.” As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.”

Spatially relative terms, such as “beneath”, “below”, “lower”, “above”, “upper” and the like, may be used herein for ease of description to describe one element or feature's relationship to another elements or features as shown in the figures.

It will be further understood that the terms “comprises” and/or “comprising,” or “include” and/or “including”, when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

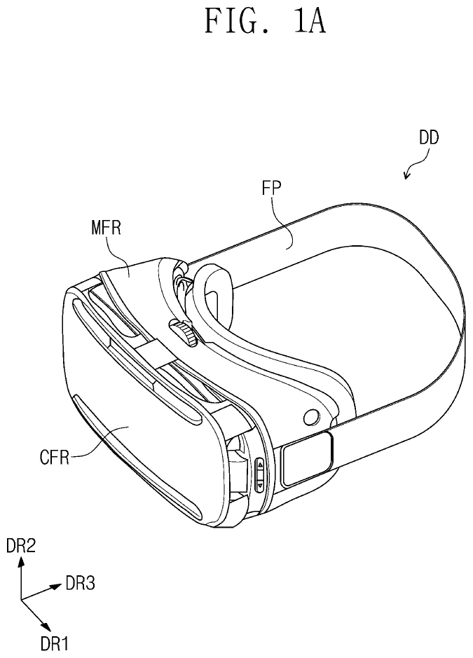

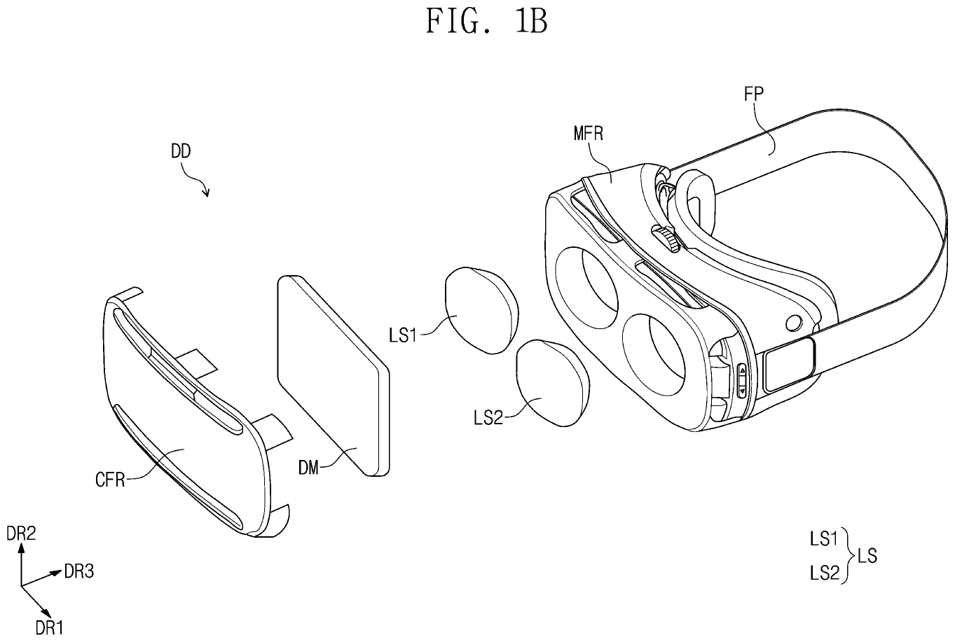

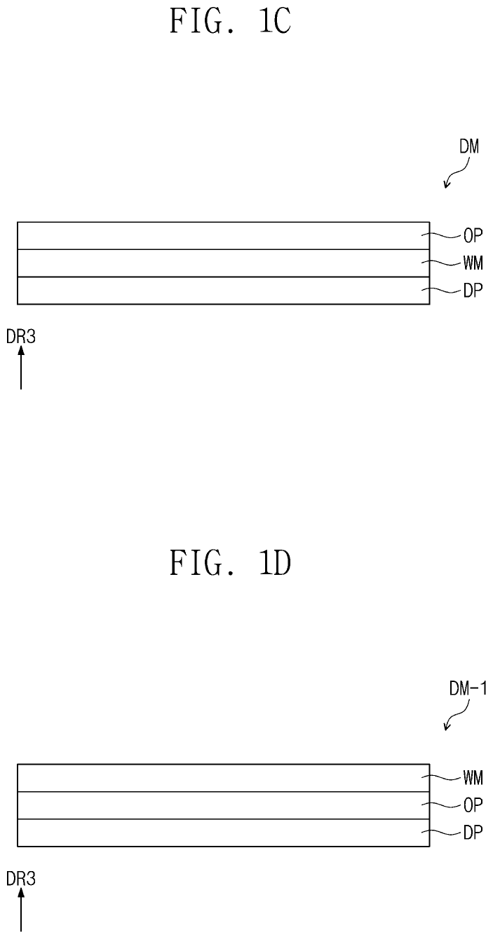

FIG. 1A is a perspective view of a display device according to an embodiment of the disclosure. FIG. 1B is an exploded perspective view of the display device according to an embodiment of the disclosure. FIGS. 1C and 1D are cross-sectional views of display modules DM and DM-1 according to embodiments of the disclosure.

An embodiment of the display device DD may be activated in response to electrical signals. In an embodiment, for example, the display device DD may be a television, a monitor, an outdoor billboard, a game unit, a personal computer, a notebook computer, a mobile phone, a tablet computer, a game unit, a navigation unit, a wearable unit, etc., however, these are merely examples. FIGS. 1A and 1B show an embodiment where the display device DD is a head-mounted display (HMD) as an example. The head-mounted display may be an electronic device that is worn on the head of a user and provides a screen on which an image or video is displayed to the user. The head-mounted display may include a see-through type head-mounted display that provides an augmented reality (AR) based on actual external objects and a see-closed type head-mounted display that provides a virtual reality (VR) to the user with a screen independent from the external objects.

Referring to FIGS. 1A and 1B, an embodiment of the display device DD may include the display module DM and a lens part LS facing the display module DM. In addition, the display device DD may include a main frame MFR, a cover frame CFR, and a fixing part FP.

The main frame MFR may be a part configured or designed to be worn on a user's face. The main frame MFR may have a shape corresponding to a shape of the user's head (face). In an embodiment, for example, a length of the fixing part FP may be adjusted according to a circumference of the user's head. The fixing part FP may be a structure that facilitates the installation of the main frame MFR and may include straps, bends, or the like, however, the disclosure should not be limited thereto or thereby. According to an embodiment, the fixing part FP may have various shapes, such as helmets or eyeglass temples, which are combined with the main frame MFR.

The main frame MFR may be coupled with the cover frame CFR to provide an accommodating space in which the lens part LS and the display module DM are accommodated.

The lens part LS may be disposed between the display module DM and the user. The lens part LS may transmit a light emitted from the display module DM and may provide the light to the user. In an embodiment, for example, the lens part LS may include at least one selected from various types of lenses, such as multi-channel lenses, convex lenses, concave lenses, spherical lenses, aspherical lenses, simple lenses, compound lenses, standard lenses, narrow-angle lenses, wide-angle lenses, fixed-focal lenses, and varifocal lenses.

The lens part LS may include a first lens LS1 and a second lens LS2. The first lens LS1 and the second lens LS2 may be arranged to correspond to positions of the user's left and right eyes. The first lens LS1 and the second lens LS2 may be accommodated in the main frame MFR.

The display module DM may be provided in a state fixed to the main frame MFR or may be provided in a state detachable from the main frame MFR. The display module DM may provide an image to the user, and the image may include a still image as well as a video. The display module DM will be described in detail later.

The cover frame CFR may be disposed on one surface of the display module DM and may protect the display module DM. The cover frame CFR and the lens part LS may be spaced apart from each other with the display module DM interposed therebetween.

In FIGS. 1A and 1B and the following drawings, first, second, and third directions DR1, DR2, and DR3 are shown, and directions indicated by the first, second, and third directions DR1, DR2, and DR3 in the following descriptions are relative to each other, and thus, the directions indicated by the first, second, and third directions DR1, DR2, and DR3 may be changed to other directions. In the following descriptions, the first direction DR1 and the second direction DR2 may be perpendicular to each other, and the third direction DR3 may be a normal line direction with respect to a plane defined by the first direction DR1 and the second direction DR2.

A thickness direction of the display device DD may be substantially parallel to the third direction DR3 that is the normal line direction with respect to a plane defined by the first direction DR1 and the second direction DR2. In an embodiment, front (or upper) and rear (or lower) surfaces of each member of the display device DD may be distinguished from each other with respect to the third direction DR3. In the following descriptions, the expression “on a plane” may mean when viewed on a plane substantially parallel to the plane defined by the first direction DR1 and the second direction DR2, and the expression “on a cross-section” may mean when viewed on a plane substantially parallel to the third direction DR3.

Referring to FIGS. 1C and 1D, an embodiment of the display module DM and DM-1 may include a display panel DP, a window member WM, and an optical member OP.

The display panel DP may have a configuration for substantially generating the image. The image generated by the display panel DP may be viewed by the user from the outside.

The display panel DP may be a light emitting type display panel, however, it should not be particularly limited. In an embodiment, for example, the display panel DP may be an organic light emitting display panel or an inorganic light emitting display panel. The organic light emitting display panel may be a display panel in which a light emitting layer includes an organic light emitting material. The inorganic light emitting display panel may be a display panel in which a light emitting layer includes a quantum dot, a quantum rod, or a micro-light emitting diode (LED). Hereinafter, for convenience of description, embodiments where the display panel is the organic light emitting display panel will be described in detail.

The window member WM may be disposed on the display panel DP. The window member WM may include an optically transparent insulating material. The window member WM may include a glass or plastic material. The window member WM may have a single-layer or multi-layer structure. In an embodiment, for example, the window member WM may include a plurality of plastic films attached to each other by an adhesive or a glass substrate and a plastic film attached to the glass substrate by an adhesive.

The optical member OP may be disposed on the display panel DP. The optical member OP may be a polarizing member, a color filter, or a wavelength filter. The optical member OP may control a light incident thereto and may improve display characteristics of the display panel DP.

In an embodiment, as shown in FIG. 1C, the optical member OP may be disposed on the window member WM in the display module DM. In an alternative embodiment, as shown in FIG. 1D, the optical member OP may be disposed between the window member WM and the display panel DP in the display module DM-1. According to another alternative embodiment, different from the display modules DM and DM-1 shown in FIGS. 1C and 1D, the optical member may be omitted from the display modules DM and DM-1.

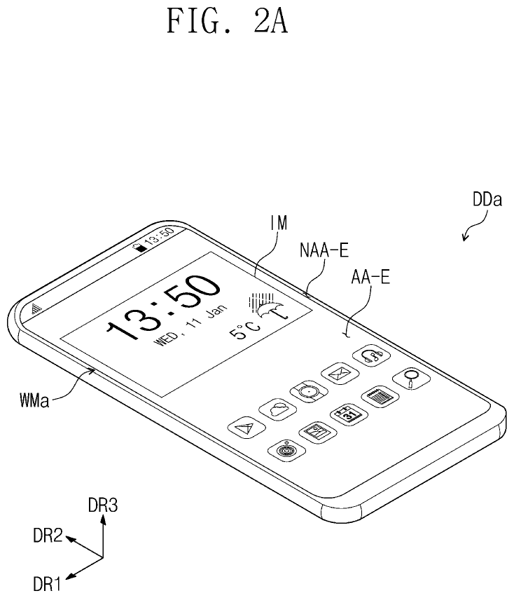

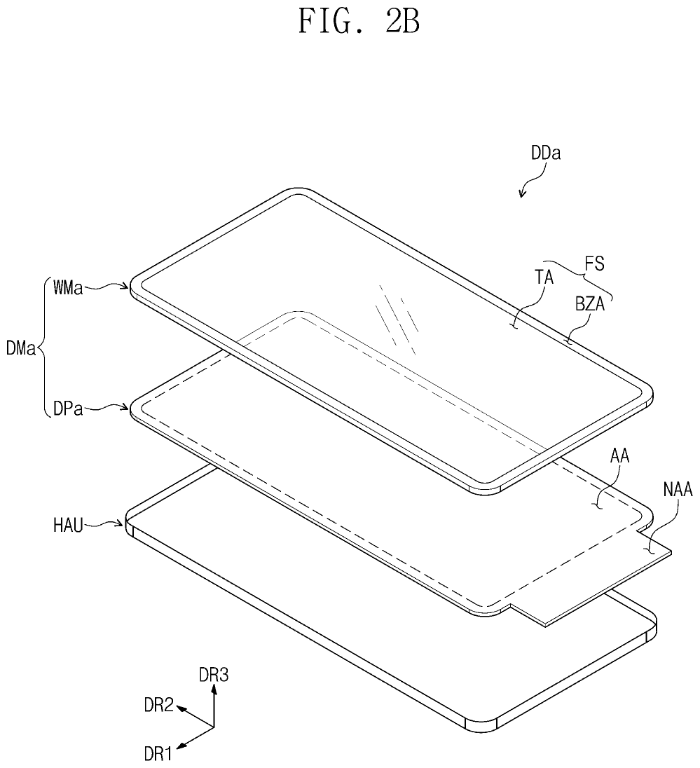

FIG. 2A is a perspective view of a display device according to an embodiment of the disclosure. FIG. 2B is an exploded perspective view of the display device according to an embodiment of the disclosure.

FIGS. 2A and 2B show an embodiment where a display device DDa is a mobile phone as an example.

An embodiment of the display device DDa may display an image IM through an active area AA-E. The active area AA-E may include a plane defined by the first direction DR1 and the second direction DR2. A peripheral area NAA-E may be defined adjacent to the active area AA-E. The peripheral area NAA-E may surround the active area AA-E. However, the peripheral area NAA-E may be defined adjacent to only one side of the active area AA-E or may be omitted.

The display device DDa may include a housing HAU and a display module DMa. The display module DMa may include a display panel DPa and a window member WMa.

The window member WMa may entirely cover an outer side of the display module DMa. The window member WMa may include a transmission area TA and a bezel area BZA. A front surface of the window member WMa including the transmission area TA and the bezel area BZA may correspond to a front surface of the display device DDa. The transmission area TA may correspond to the active area AA-E of the display device DDa shown in FIG. 2A, and the bezel area BZA may correspond to the peripheral area NAA-E of the display device DDa shown in FIG. 2A.

The transmission area TA may be an optically transparent area. The bezel area BZA may have a light transmittance lower than that of the transmission area TA. The bezel area BZA may have a predetermined color. The bezel area BZA may be defined adjacent to the transmission area TA and may surround the transmission area TA. However, the bezel area BZA may be defined to be adjacent to only one side of the transmission area TA or may be partially omitted.

In an embodiment, as shown in FIG. 2B The display panel DPa may include an active area AA and a peripheral area NAA. The active area AA may be activated in response to electrical signals. In an embodiment, an image IM (refer to FIG. 2A) may be displayed through the active area AA. The active area AA of the display panel DPa may correspond to the active area AA-E of the display device DDa shown in FIG. 2A, and the peripheral area NAA of the display panel DPa may correspond to the peripheral area NAA-E of the display device DDa shown in FIG. 2A. The transmission area TA may overlap at least a portion of the active area AA. The peripheral area NAA may be covered by the bezel area BZA.

Although not shown in FIGS. 2A and 2B, an input sensing unit may be provided on the display panel DPa. The input sensing unit may sense an external input applied thereto from the outside. The external input may be a user input. The user input may include various types of external inputs, such as a part of a user's body, light, heat, pen, or pressure. The input sensing unit may be disposed directly on the display panel DPa or may be attached to the display panel DPa by a separate adhesive member.

In the disclosure, when an element (or area, layer, or portion) is referred to as being “directly disposed” on another element, there are no intervening elements between the element and another element. That is, the expression “an element is disposed directly on another element.” means that the element is directly in contact with another element”.

The housing HAU may accommodate the display panel DPa. The housing HAU may be coupled with the window member WMa.

In such embodiments, features of the active area AA-E and the peripheral area NAA-E of the display device DDa, the transmission area TA and the bezel area BZA of the window member WMa, and the active area AA and the peripheral area NAA of the display panel Dpa, which are described above with reference to FIGS. 2A and 2B, may be applied to the display device DD, the window member WM, and the display panel DP with reference to FIGS. 1A to 1D.

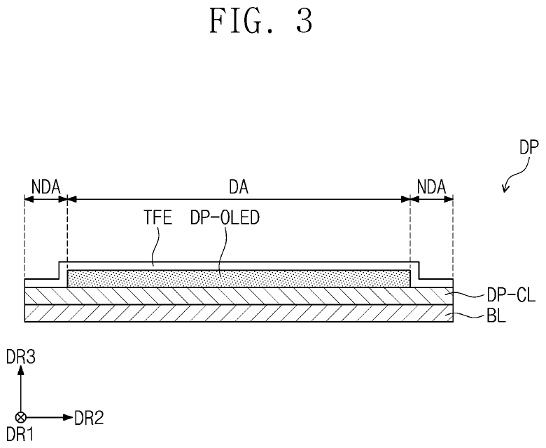

FIG. 3 is a cross-sectional view of a display panel DP according to an embodiment of the disclosure. Particularly, FIG. 3 shows a cross-section of the display panel DP when viewed in the first direction DR1.

Referring to FIG. 3, an embodiment of the display panel DP may include a base layer BL, a circuit layer DP-CL disposed on the base layer BL, a display element layer DP-OLED disposed on the circuit layer DP-CL, and a thin film encapsulation layer TFE disposed on the display element layer DP-OLED.

The base layer BL may include a display area DA and a non-display area NDA around the display area DA. The base layer BL may include a flexible plastic material such as polyimide (PI). The display element layer DP-OLED may be disposed in the display area DA.

A plurality of pixels may be disposed in the circuit layer DP-CL and the display element layer DP-OLED. Each pixel may include transistors disposed in the circuit layer DP-CL and a light emitting element disposed in the display element layer DP-OLED and connected to the transistors. The pixel will be described in detail later.

The thin film encapsulation layer TFE may be disposed on the circuit layer DP-CL to cover the display element layer DP-OLED. The thin film encapsulation layer TFE may protect the pixels from moisture, oxygen, and a foreign substance such as dust particles.

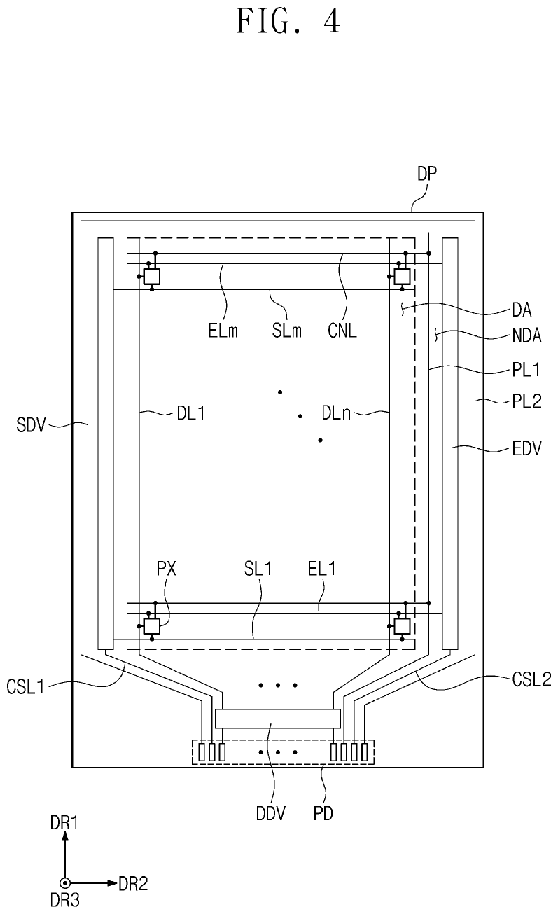

FIG. 4 is a plan view of the display panel DP according to an embodiment of the disclosure.

Referring to FIG. 4, an embodiment of the display device DD may include the display panel DP, a scan driver SDV, a data driver DDV, an emission driver EDV, and a plurality of pads PD.

The display panel DP may have a rectangular shape with long sides extending in the first direction DR1 and short sides extending in the second direction DR2, however, the shape of the display panel DP should not be limited thereto or thereby. The display panel DP may include the display area DA and the non-display area NDA surrounding the display area DA.

The display panel DP may include the pixels PX, a plurality of scan lines SL1 to SLm, a plurality of data lines DL1 to DLn, a plurality of emission lines EL1 to ELm, first and second control lines CSL1 and CSL2, first and second power lines PL1 and PL2, and connection lines CNL. Each of “m” and “n” is a natural number.

The pixels PX may be arranged in the display area DA. The scan driver SDV and the emission driver EDV may be disposed in the non-display area NDA respectively adjacent to the long sides of the display panel DP. The data driver DDV may be disposed in the non-display area NDA to be adjacent to one short side of the short sides of the display panel DP. When viewed in a plane (i.e., when in the third direction DR3), the data driver DDV may be disposed to be adjacent to a lower end of the display panel DP.

The scan lines SL1 to SLm may extend in a direction parallel to the second direction DR2 and may be connected to the pixels PX and the scan driver SDV. The data lines DL1 to DLn may extend in a direction parallel to the first direction DR1 and may be connected to the pixels PX and the data driver DDV. The emission lines EL1 to ELm may extend in the second direction DR2 and may be connected to the pixels PX and the emission driver EDV.

The first power line PL1 may extend in the first direction DR1 and may be disposed in the non-display area NDA. The first power line PL1 may be disposed between the display area DA and the emission driver EDV.

The connection lines CNL may extend in the second direction DR2 and may be arranged in the first direction DR1. The connection lines CNL may be connected to the first power line PL1 and the pixels PX. A first voltage may be applied to the pixels PX through the first power line PL1 and the connection lines CNL connected to the first power line PL1. The connection lines CNL may be defined as portions of the first power line PL1 that receives the first voltage.

The second power line PL2 may be disposed in the non-display area NDA. The second power line PL2 may extend along the long sides of the display panel DP and the other short side at which the data driver DDV is not disposed in the display panel DP. The second power line PL2 may be disposed outside the scan driver SDV and the emission driver EDV.

Although not shown in figures, the second power line PL2 may extend to the display area DA and may be connected to the pixels PX. A second voltage having a level lower than that of the first voltage may be applied to the pixels PX through the second power line PL2.

The first control line CSL1 may be connected to the scan driver SDV and may extend toward the lower end of the display panel DP when viewed in the plane. The second control line CSL2 may be connected to the emission driver EDV and may extend toward the lower end of the display panel DP when viewed in the plane. The data driver DDV may be disposed between the first control line CSL1 and the second control line CSL2.

The pads PD may be disposed in the non-display area NDA adjacent to the lower end of the display panel DP. The pads PD may be disposed closer to the lower end of the display panel DP than the data driver DDV is. The data driver DDV, the first power line PL1, the second power line PL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

Although not shown in figures, the display device DD may further include a timing controller to control an operation of the scan driver SDV, the data driver DDV, and the emission driver EDV and a voltage generator to generate the first and second voltages. The timing controller and the voltage generator may be connected to corresponding pads PD through a printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The emission driver EDV may generate a plurality of emission signals, and the emission signals may be applied to the pixels PX through the emission lines EL1 to ELm.

The pixels PX may receive the data voltages in response to the scan signals. The pixels PX may emit a light having a luminance corresponding to the data voltages in response to the emission signals, and thus, the image may be displayed.

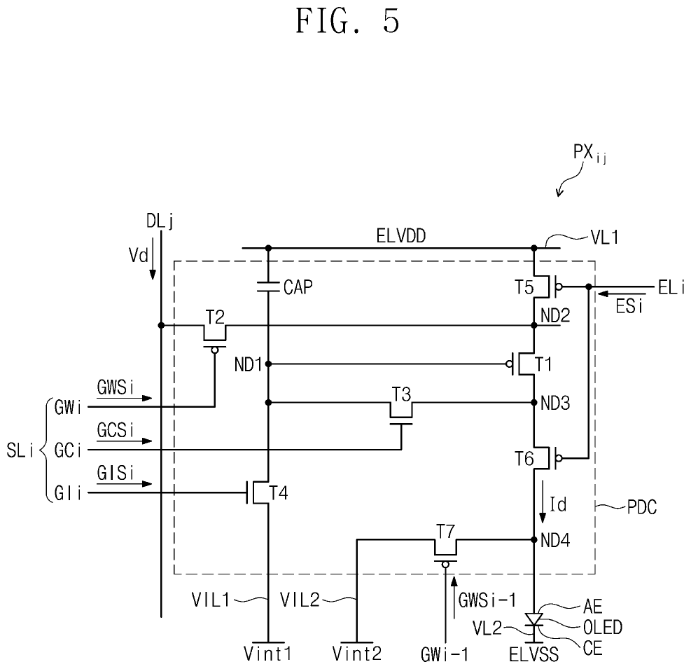

FIG. 5 is an equivalent circuit diagram of a pixel PXᵢⱼ according to an embodiment of the disclosure. FIG. 5 shows a pixel PXᵢⱼ connected to an i-th scan line SLi, an i-th emission line ELi, and a j-th data line DLj as an example. Here, i and j denote a natural number.

Referring to FIG. 5, in an embodiment, the pixel PXᵢⱼ may include a light emitting element OLED and a pixel driving circuit PDC electrically connected to the light emitting element OLED. The pixel driving circuit PDC may include transistors T1 to T7 and a capacitor CAP. The transistors T1 to T7 and the capacitor CAP may control an amount of a current flowing through the light emitting element OLED, and the light emitting element OLED may generate a light with a predetermined luminance corresponding to the amount of the current supplied thereto.

The i-th scan line SLi may include i-th first, second, and third scan lines GWi, GCi, and Gli. The first scan line GWi that receives an i-th write scan signal GWSi may be defined as a write scan line GWi. The second scan line GCi that receives an i-th compensation scan signal GCSi may be defined as a compensation scan line GCi. The third scan line Gli that receives an i-th initialization scan signal GISi may be defined as an initialization scan line GIi.

The transistors T1 to T7 may include first, second, third, fourth, fifth, sixth, and seventh transistors T1, T2, T3, T4, T5, T6, and T7. Each of the first to seventh transistors T1 to T7 may include a source electrode, a drain electrode, and a gate electrode. Hereinafter, the source electrode, the drain electrode, and the gate electrode may be referred to as a source, a drain, and a gate, respectively.

In the disclosure, the expression “a transistor is connected to a signal line” means that one electrode of a source electrode, a drain electrode, and a gate electrode of the transistor is provided integrally with the signal line or connected to the signal line via a connection electrode. In addition, the expression “a transistor is electrically connected to another transistor” means that one electrode of a source electrode, a drain electrode, and a gate electrode of the transistor is provided integrally with one electrode of a source electrode, a drain electrode, and a gate electrode of another transistor or connected to one electrode of the source electrode, the drain electrode, the gate electrode of another transistor via a connection electrode.

Each of the first to seventh transistors T1 to T7 may be a transistor including an oxide semiconductor layer or a transistor including a low-temperature polycrystalline silicon (LTPS) semiconductor layer. Each of the first to seventh transistors T1 to T7 may be a P-type transistor or an N-type transistor. In an embodiment, for example, each of the first, second, fifth, sixth, and seventh transistors T1, T2, T5, T6, and T7 may be a p-channel metal-oxide-semiconductor (PMOS) transistor including the LTPS semiconductor layer, and each of the third and fourth transistors T3 and T4 may be an n-channel metal-oxide-semiconductor (NMOS) transistor including the oxide semiconductor layer, however, the first to seventh transistors T1 to T7 should not be limited thereto or thereby. In addition, the pixel driving circuit PDC shown in FIG. 5 includes seven transistors T1 to T7, however, the number of transistors included in the pixel driving circuit PDC should not be limited thereto or thereby.

The light emitting element OLED may be defined as an organic light emitting element. The light emitting element OLED may include a first electrode AE and a second electrode CE. In an embodiment, for example, the first electrode AE may be an anode, and the second electrode CE may be a cathode. The first electrode AE of the light emitting element OLED may be electrically connected to a first voltage line VL1 that receives a first driving voltage ELVDD. The second electrode CE of the light emitting element OLED may be electrically connected to a second voltage line VL2 that receives a second driving voltage ELVSS.

The first transistor T1 may be electrically connected between the first voltage line VL1 that receives the first driving voltage ELVDD and the light emitting element OLED. The first transistor T1 may include the source connected to a second node ND2, the drain connected to a third node ND3, and the gate connected to a first node N1. The first transistor T1 may be turned on in response to a voltage at the first node ND1. The first transistor T1 may receive a data voltage Vd transmitted by the data line DLj in response to a switching operation of the second transistor T2 and may supply a driving current Id to the light emitting element OLED. In such an embodiment, the first transistor T1 may be defined as a driving transistor.

The second transistor T2 may be electrically connected between the data line DLj and the first transistor T1. The second transistor T2 may include the source connected to the data line DLj, the drain connected to the second node ND2, and the gate connected to the first scan line GWi. The second transistor T2 and the first transistor T1 may be connected to each other at the second node ND2. The second transistor T2 may be turned on in response to the write scan signal GWSi applied thereto via the first scan line GWi. The data voltage Vd applied to the data line DLj via the turned-on second transistor T2 may be transmitted to the source of the first transistor T1. In such an embodiment, the second transistor T2 may be defined as a switching transistor.

The third transistor T3 may be electrically connected between the fourth transistor T4 and the first transistor T1. The third transistor T3 may include the source connected to the first node ND1, the drain connected to the third node ND3, and the gate connected to the second scan line GCi. The third transistor T3 and the first transistor T1 may be connected to each other at the third node ND3. The third transistor T3 may be turned on in response to the compensation scan signal GCSi applied thereto via the second scan line GCi. The gate of the first transistor T1 may be electrically connected to the drain of the first transistor T1 by the turned-on third transistor T3, and the first transistor T1 may be connected in a diode configuration. In such an embodiment, the third transistor T3 may be defined as a compensation transistor.

The fourth transistor T4 may be electrically connected between a first initialization line VIL1 to which a first initialization voltage Vint1 is applied and the third transistor T3. The fourth transistor T4 may include the source connected to the first initialization line VIL1, the drain connected to the first node ND1, and the gate connected to the third scan line Gli. The fourth transistor T4 may be turned on in response to the initialization scan signal GISi applied thereto via the third scan line Gli. The turned-on fourth transistor T4 may transmit the first initialization voltage Vint1 to the first node ND1 to initialize an electric potential of the gate of the first transistor T1. In such an embodiment, the fourth transistor T4 may be defined as an initialization transistor.

The fifth transistor T5 may be electrically connected between the first voltage line VL1 that receives the first driving voltage ELVDD and the first transistor T1. The fifth transistor T5 may include the source connected to the first voltage line VL1, the drain connected to the second node ND2, and the gate connected to the emission line ELi.

The sixth transistor T6 may be electrically connected between the first transistor T1 and the light emitting element OLED. The sixth transistor T6 may include the source connected to the third node ND3, the drain connected to the first electrode AE of the light emitting element OLED via a fourth node ND4, and the gate connected to the emission line ELi.

The fifth transistor T5 and the sixth transistor T6 may be turned on in response to the emission signal ESi applied thereto via the emission line ELi. An emission time of the light emitting element OLED may be controlled by the emission signal ESi. When the fifth transistor T5 and the sixth transistor T6 are turned on, the driving current Id may be generated based on a voltage difference between a gate voltage of the gate of the first transistor T1 and the first driving voltage ELVDD, the driving current Id may be supplied to the light emitting element OLED via the sixth transistor T6, and thus, the light emitting element OLED may emit the light. In such an embodiment, each of the fifth transistor T5 and the sixth transistor T6 may be defined as a light emission control transistor.

The seventh transistor T7 may be electrically connected between the sixth transistor T6 and a second initialization line VIL2 to which a second initialization voltage Vint2 is applied. The seventh transistor T7 may include the source connected to the fourth node ND4, the drain connected to the second initialization line VIL2, and the gate connected to the first scan line GWi-1. The gate of the seventh transistor T7 may be connected to an (i-1)-th write scan line GWi-1 that is a previous write scan line of the i-th write scan line GWi, however, it should not be limited thereto or thereby. According to an embodiment, the gate of the seventh transistor T7 may be electrically connected to a separate fourth scan line.

The seventh transistor T7 may be turned on in response to an (i-1)-th write scan signal GWSi-1 applied thereto via the first scan line GWi-1. The turned on seventh transistor T7 may transmit the second initialization voltage Vint2 to the fourth node ND4. The second initialization voltage Vint2 may have the same level as the first initialization voltage Vint1, however, it should not be limited thereto or thereby. According to an embodiment, the second initialization voltage Vint2 may have a level different from that of the first initialization voltage Vint1. In such an embodiment, the seventh transistor T7 may be defined as an initialization transistor.

The seventh transistor T7 may improve the ability to display a black color of the pixel PXᵢⱼ. A portion of the driving current Id may be bypassed as a bypass current via the seventh transistor T7. In a case where a black image is displayed, a current reduced by an amount of the bypass current, which is bypassed through the seventh transistor T7, from the driving current Id may be provided to the light emitting element OLED, and thus, the black image may be clearly displayed. That is, the pixel PX may display an accurate black luminance image using the seventh transistor T7, such that a contrast ratio of the display device DD (refer to FIG. 1A) may be improved.

The capacitor CAP may include a first electrode that receives the first driving voltage ELVDD and a second electrode connected to the first node ND1. The capacitor CAP may be charged with electric charges corresponding to a difference in voltage between the first electrode and the second electrode. When the fifth transistor T5 and the sixth transistor T6 are turned on, the amount of current flowing through the first transistor T1 may be determined based on the voltage charged in the capacitor CAP.

The configuration of the pixel driving circuit PDC shown in FIG. 5 is merely an example, and the configuration of the pixel driving circuit PDC may be changed without being limited to the embodiment shown in FIG. 5.

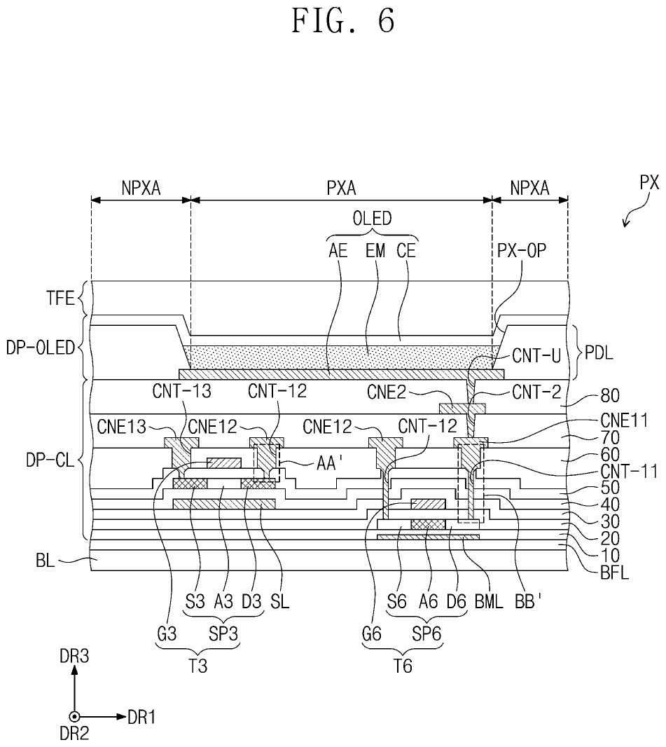

FIG. 6 is a cross-sectional view of the display panel DP according to an embodiment of the disclosure. FIG. 6 shows the light emitting element OLED and some transistors T3 and T6 of the pixel driving circuit PDC (refer to FIG. 5), which is connected to the light emitting element OLED, as an example. Features of the components of the display panel DP described above may be applied to the same or like components of the display panel DP shown in FIG. 6.

Referring to FIG. 6, an embodiment of the display panel DP may include the base layer BL, the circuit layer DP-CL, the display element layer DP-OLED, and the encapsulation layer TFE.

The base layer BL may provide a base surface on which the circuit layer DP-CL is disposed. The circuit layer DP-CL may include insulating layers BFL and 10 to 80, the transistors T3 and T6, and connection electrodes CNE11 to CNE13 and CNE2. The insulating layers BFL and 10 to 80 may include a buffer layer BFL and first, second, third, fourth, fifth, sixth, seventh, and eighth insulating layers 10, 20, 30, 40, 50, 60, 70, and 80 disposed on the buffer layer BFL. However, the insulating layers included in the circuit layer DP-CL should not be limited thereto or thereby and may be changed depending on components of the pixel driving circuit included in the circuit layer DP-CL and processes for the circuit layer DP-CL.

The buffer layer BFL may be disposed on the base layer BL. The buffer layer BFL may include at least one inorganic layer. In an embodiment, for example, the buffer layer BFL may include at least one selected from aluminum oxide, titanium oxide, silicon oxide, silicon nitride, silicon oxynitride, zirconium oxide, and hafnium oxide. The buffer layer BFL may improve an adhesive force between the base layer BL and a semiconductor pattern layer, e.g., a sixth semiconductor pattern SP6 or a conductive pattern layer of the circuit layer DP-CL disposed on the base layer BL.

Each of the first to eighth insulating layers 10 to 80 may include an inorganic layer and/or an organic layer and may have a single-layer or multi-layer structure. The inorganic layer may include at least one selected from aluminum oxide, titanium oxide, silicon oxide, silicon nitride, silicon oxynitride, zirconium oxide, and hafnium oxide, however, a material for the inorganic layer should not be limited thereto or thereby. The organic layer may include at least one selected from an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. However, a material for the organic layer should not be limited thereto or thereby.

A light shielding pattern BML may be disposed on the buffer layer BFL. In an alternative embodiment where the buffer layer BFL is omitted, the light shielding pattern BML may be disposed directly on the base layer BL. The light shielding pattern BML may include molybdenum. The light shielding pattern BML may have a shielding function. The light shielding pattern BML may prevent an electric potential, which is caused by a polarization phenomenon between the insulating layers 10 to 80 disposed on the light shielding pattern BML, from exerting influence on the transistors T1 to T7 (refer to FIG. 5).

The sixth semiconductor pattern SP6 may be disposed on the first insulating layer 10. The sixth semiconductor pattern SP6 may include a silicon semiconductor. In an embodiment, for example, the sixth semiconductor pattern SP6 may include polysilicon or amorphous silicon. However, it should not be limited thereto or thereby as long as the sixth semiconductor pattern SP6 has a semiconductor property.

The sixth semiconductor pattern SP6 may include plural regions having different electrical properties depending on whether it is doped or not or whether it is doped with an N-type dopant or a P-type dopant. A first semiconductor pattern layer may include a first region having a high conductivity and a second region having a low conductivity. The first region may be doped with the N-type dopant or the P-type dopant. A P-type transistor may include a doped region doped with the P-type dopant, and an N-type transistor may include a doped region doped with the N-type dopant. The second region may be a non-doped region or a region doped with a relatively low concentration compared with the first region.

The first region may have the conductivity greater than that of the second region and may substantially serve as a source and a drain of a transistor. The second region may substantially correspond to a channel (or an active) of the transistor. In other words, the first region, which has the relatively high conductivity, of the first semiconductor pattern layer may be the source or drain of the transistor or a connection signal line, and the second region, which has the relatively low conductivity, of the first semiconductor pattern layer may be the channel of the transistor.

The sixth semiconductor pattern SP6 may include a sixth source S6, a sixth channel A6, and a sixth drain D6. The sixth source S6 and the sixth drain D6 may extend in opposite directions to each other from the sixth channel A6. That is, the sixth source S6 and the sixth drain D6 may be spaced apart from each other with the sixth channel A6 interposed therebetween.

The first insulating layer 10 may be disposed on the buffer layer BFL. The first insulating layer 10 may cover the light shielding pattern BML. The second insulating layer 20 may be disposed on the first insulating layer 10. The second insulating layer 20 may cover the sixth semiconductor pattern SP6.

A sixth gate electrode G6 may be disposed on the second insulating layer 20. The sixth gate electrode G6 may overlap the sixth channel A6. According to an embodiment, the sixth gate electrode G6 may serve as a mask in a process of doping the sixth semiconductor pattern SP6.

FIG. 6 shows an embodiment having a top-gate structure in which the sixth transistor T6 includes the sixth gate electrode G6 disposed on the sixth semiconductor pattern SP6 as an example, however, the disclosure should not be limited thereto or thereby. According to an alternative embodiment, the sixth transistor T6 may have a bottom-gate structure in which the sixth gate electrode G6 is disposed under the sixth semiconductor pattern SP6.

In an embodiment, the first, second, fifth, and seventh transistors T1, T2, T5, and T7 (refer to FIG. 5) may have a same structure as the sixth transistor T6. In an embodiment, for example, semiconductor patterns of the first, second, fifth, and seventh transistors T1, T2, T5, and T7 (refer to FIG. 5) may be formed from (or defined by portions of) the first semiconductor pattern layer in a same way as the sixth semiconductor pattern SP6, and gate electrodes of the first, second, fifth, and seventh transistors T1, T2, T5, and T7 (refer to FIG. 5) may be formed from the first conductive pattern layer in a same way as the sixth gate electrode G6, however, the disclosure should not be limited thereto or thereby.

The third insulating layer 30 may be disposed on the second insulating layer 20. The third insulating layer 30 may cover the sixth gate electrode G6.

A scan line SL may be disposed on the third insulating layer 30. The scan line SL may correspond to portions of the first, second, and third scan lines GWi, GCi, and GIi (refer to FIG. 5).

The fourth insulating layer 40 may be disposed on the third insulating layer 30. The fourth insulating layer 40 may cover the scan line SL.

A third semiconductor pattern SP3 may be disposed on the fourth insulating layer 40. The third semiconductor pattern SP3 may include an oxide semiconductor including a metal oxide. In an embodiment, for example, the oxide semiconductor may include a metal oxide of metals, such as zinc (Zn), indium (In), gallium (Ga), tin (Sn), titanium (Ti), etc., or a mixture of the metals, such as zinc (Zn), indium (In), gallium (Ga), tin (Sn), titanium (Ti), etc., and oxides thereof. The oxide semiconductor may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), zinc-tin oxide (ZTO), or the like. However, the disclosure should not be limited thereto or thereby.

The third semiconductor pattern SP3 may include a plurality of areas having different electrical properties depending on whether the metal oxide is reduced or not. An area (hereinafter, referred to as a reduced area) where the metal oxide is reduced may have a conductivity higher than that of an area (hereinafter, referred to as a non-reduced area) where the metal oxide is not reduced. The reduced area may substantially act as the source or the drain of the transistor. The non-reduced area may substantially correspond to the channel (or the active) of the transistor.

The third semiconductor pattern SP3 may include a third source S3, a third channel A3, and a third drain D3. The third source S3 and the third drain D3 may extend in opposite directions to each other from the third channel A3. That is, the third source S3 and the third drain D3 may be spaced apart from each other with the third channel A3 interposed therebetween when viewed in the plane.

The fifth insulating layer 50 may be disposed on the fourth insulating layer 40. The fifth insulating layer 50 may cover the third semiconductor pattern SP3.

A third gate electrode G3 may be disposed on the fifth insulating layer 50. The third gate electrode G3 may overlap the third channel A3. According to an embodiment, the third gate electrode G3 may serve as a mask in a process of doping the third semiconductor pattern SP3.

The third semiconductor pattern SP3 may overlap a portion of the scan line SL disposed thereunder. The portion of the scan line SL, which overlaps the third semiconductor pattern SP3, may act as a third gate of the third transistor T3 together with the third gate electrode G3. In this case, the third gate of the third transistor T3 may be formed in a double-layer structure, and thus, the third gate of the third transistor T3 may have a sufficient amount of gate charge and may be switched at high speed. In addition, as the scan line SL is disposed to overlap the third semiconductor pattern SP3, damages caused on the third semiconductor pattern SP3 by a light traveling to the display panel DP from a lower side of the display panel DP may be effectively prevented. However, the structure of the third transistor T3 described above is merely an example, and the disclosure should not be limited thereto or thereby.

In an embodiment, the fourth transistor T4 (refer to FIG. 5) may have a same structure as the third transistor T3. In an embodiment, for example, a semiconductor pattern of the fourth transistor T4 (refer to FIG. 5) may be formed from a second semiconductor pattern layer in the same way as the third semiconductor pattern SP3, and the gate electrode of the fourth transistor T4 (refer to FIG. 5) may be formed from a third conductive pattern layer in the same way as the third gate electrode G3. However, the disclosure should not be limited thereto or thereby.

The third semiconductor pattern SP3 of the third transistor T3 and the sixth semiconductor pattern SP6 of the sixth transistor T6 may be disposed in (or directly on) different layers from each other, however, the disclosure should not be limited thereto or thereby. According to an embodiment, the semiconductor patterns of all transistors included in the pixel driving circuit PDC (refer to FIG. 5) may be disposed in (or directly on) a same layer as each other.

The sixth insulating layer 60 may be disposed on the fifth insulating layer 50. The sixth insulating layer 60 may cover the third gate electrode G3.

The connection electrodes CNE11 to CNE13 may be disposed on the sixth insulating layer 60. Each of the connection electrodes CNE11 to CNE13 may have a structure in which metal materials are sequentially stacked, e.g., a structure of titanium (Ti)/aluminum (Al)/titanium (Ti). The connection electrodes CNE11 to CNE13 may include first-first, first-second, and first-third connection electrodes CNE11, CNE12, and CNE13. The first-first to first-third connection electrodes CNE11 to CNE13 may be disposed spaced apart from each other on the same layer, for example, the sixth insulating layer 60. For the convenience of illustration and description, FIG. 6 shows an embodiment having a structure in which the connection electrodes CNE11 to CNE13 entirely overlap contact holes CNT-11, CNT-12, and CNT-13 when viewed in the plane and have a flat upper surface, however, the connection electrodes CNE11 to CNE13 should not be limited thereto or thereby. According to an embodiment, the connection electrodes CNE11 to CNE13 may be arranged along an inner surface of the insulating layer 60 defining each of the contact holes CNT-11, CNT-12, and CNT-13 and may not overlap a center of each of the contact holes CNT-11, CNT-12, and CNT-13 when viewed in the plane.

The first-first connection electrode CNE11 may be connected to the sixth drain D6 of the sixth transistor T6. The first-first connection electrode CNE11 may be connected to the sixth drain D6 via the contact hole CNT-11 defined through the second to sixth insulating layers 20 to 60.

The first-second connection electrode CNE12 may be connected to the sixth source S6 of the sixth transistor T6. The first-second connection electrode CNE12 may be connected to the sixth source S6 via the contact hole CNT-12 defined through the second to sixth insulating layers 20 to 60.

When viewed in the plane, the first-second connection electrode CNE12 may extend and may overlap the third drain D3 of the third transistor T3. The first-second connection electrode CNE12 may be connected to the third drain D3 via the contact hole CNT-12 defined through the fifth and sixth insulating layers 50 and 60. Accordingly, the third semiconductor pattern SP3 of the third transistor T3 and the sixth semiconductor pattern SP6 of the sixth transistor T6, which are disposed in (or directly on) different layers from each other, may be electrically connected to each other by the first-second connection electrode CNE12.

The first-third connection electrode CNE13 may be connected to the third source S3 of the third transistor T3. The first-third connection electrode CNE13 may be connected to the third source S3 via the contact hole CNT-13 defined through the fifth and sixth insulating layers 50 and 60.

The seventh insulating layer 70 may be disposed on the sixth insulating layer 60. The seventh insulating layer 70 may cover the first-first to first-third connection electrodes CNE11 to CNE13. In such an embodiment, the seventh insulating layer 70 may be referred to as a first organic layer.

A second connection electrode CNE2 may be disposed on the seventh insulating layer 70. In addition, although not shown in figures, some of the signal lines included in the display panel DP may be formed from a fifth conductive pattern layer. In such an embodiment, the second connection electrode CNE2 may be referred to as an upper connection electrode.

The second connection electrode CNE2 may be connected to the first-first connection electrode CNE11 via a contact hole CNT-2 defined through the seventh insulating layer 70. FIG. 6 shows an embodiment having a structure in which a width of the contact hole CNT-2 defined through the seventh insulating layer 70 is less than a width of the contact hole CNT1-2 defined through the fifth and sixth insulating layers 50 and 60, however, the disclosure should not be limited thereto or thereby. According to an alternative embodiment, the width of the contact hole CNT-2 defined through the seventh insulating layer 70 may be greater than the width of the contact hole CNT-12 defined through the fifth and sixth insulating layers 50 and 60.

Although not shown in figures, in an embodiment where the contact hole CNT-2 formed through the seventh insulating layer 70 is provided in plural, a separation distance between the contact holes CNT-2 defined through the seventh insulating layer 70 may be greater than a separation distance between the contact holes CNT-12 defined through the fifth and sixth insulating layers 50 and 60. Accordingly, the width of the contact hole CNT-2 defined through the seventh insulating layer 70 may be greater than the width of the contact hole CNT-12 defined through the fifth and sixth insulating layers 50 and 60.

The second connection electrode CNE2 may be connected to the sixth drain D6 of the sixth transistor T6 via the first-first connection electrode CNE11, however, is should not be limited thereto or thereby. According to an embodiment, the second connection electrode CNE2 may be omitted, or an additional connection electrode may be further disposed between the second connection electrode CNE2 and the first-first connection electrode CNE11 in the circuit layer DP-CL.

The eighth insulating layer 80 may be disposed on the seventh insulating layer 70. The eighth insulating layer 80 may cover the second connection electrode CNE2. In such an embodiment, the eighth insulating layer 80 may be referred to as a second organic layer.

At least one selected from the seventh insulating layer 70 and the eighth insulating layer 80 may include an organic layer. The organic layer may cover particles existing on a surface of layers disposed thereunder or a step difference between components disposed thereunder to provide a flat surface. In addition, the organic layer may relieve a stress between components disposed thereon and components disposed thereunder.

The display element layer DP-OLED may be disposed on the circuit layer DP-CL. The display element layer DP-OLED may include a pixel definition layer PDL and the light emitting elements OLED. Each of the light emitting elements OLED may include the first electrode AE, a light emitting layer EM, and the second electrode CE.

The light emitting elements OLED may include an organic light emitting element, a quantum dot light emitting element, a micro-LED, or a nano-LED, however, the disclosure should not be limited thereto or thereby. According to an embodiment, the light emitting elements OLED may include various types of light emitting elements as long as they emit lights or control an amount of lights in response to electrical signals.

Each of the light emitting elements OLED may be electrically connected to the transistor of the corresponding pixel driving circuit PDC (refer to FIG. 5). FIG. 6 shows an embodiment having a structure in which each of the light emitting elements OLED is electrically connected to a corresponding sixth transistor T6 as an example.

The first electrodes AE of the light emitting elements OLED may be disposed at an uppermost position of the circuit layer DP-CL. In an embodiment, for example, the first electrodes AE may be disposed on the eighth insulating layer 80. The first electrodes AE may be disposed spaced apart from each other on the eighth insulating layer 80. The first electrodes AE may be connected to a corresponding second connection electrode CNE2 via a contact hole CNT-U defined through the eighth insulating layer 80. The first electrodes AE may be electrically connected to the sixth drain D6 by a corresponding second connection electrode CNE2 and a corresponding first-first connection electrode CNE11.

The pixel definition layer PDL may be disposed at the uppermost position of the circuit layer DP-CL. In an embodiment, for example, the pixel definition layer PDL may be disposed on the eighth insulating layer 80. The pixel definition layer PDL may be provided with light emitting openings PX-OP respectively overlapping the first electrodes AE and exposing a portion of a corresponding first electrode AE. In an embodiment, areas of the first electrodes AE exposed through the light emitting openings PX-OP may correspond to light emitting areas PXA. That is, the display area DA of the display panel DP may include the light emitting areas PXA. An area in which the pixel definition layer PDL is disposed may correspond to a non-light-emitting area NPXA. When viewed in the plane, the non-light-emitting area NPXA may surround the light emitting areas PXA and may define a boundary of the light emitting areas PXA.

The pixel definition layer PDL may include a polymer resin. In an embodiment, for example, the pixel definition layer PDL may include a polyacrylate-based resin or a polyimide-based resin, however, the disclosure should not be limited thereto or thereby. According to an embodiment, the pixel definition layer PDL may further include an inorganic material.

The pixel definition layer PDL may further include a light absorbing material. The pixel definition layer PDL may include a black coloring agent such as a black pigment or a black dye. In an embodiment, for example, the black coloring agent may include a metal material, such as carbon black, chrome, etc., or an oxide thereof. However, the pixel definition layer PDL should not be limited thereto or thereby.

The light emitting layer EM may be disposed on the first electrode AE. The light emitting layers EM of the light emitting elements OLED may be provided in the form of light emitting patterns respectively disposed in the light emitting openings PX-OP and spaced apart from each other when viewed in the plane, however, the disclosure should not be limited thereto or thereby. According to an embodiment, the light emitting layers EM of the light emitting elements OLED may be provided in a common layer that is integrally formed as a single part. The light emitting layer EM may include an organic light emitting material and/or an inorganic light emitting material. In an embodiment, for example, the light emitting layer EM may include a fluorescent material, a phosphorescent material, an organometallic complex light emitting material, or a quantum dot. The light emitting layer EM may emit a color light having one of red, green, and blue colors.

The second electrode CE may be disposed on the light emitting layer EM. The second electrode CE of the light emitting elements OLED may be provided in a common layer integrally formed as a single part and may overlap the light emitting areas PXA and the non-light-emitting area NPXA. The second electrode CE may be commonly disposed in the pixels PX (refer to FIG. 4) and may receive a common voltage.

In an embodiment, the light emitting elements OLED may further include a light emitting control layer disposed between the first electrode AE and the second electrode CE. In an embodiment, for example, the light emitting control layer may include a hole control layer disposed between the first electrode AE and the light emitting layer EM or an electron control layer disposed between the light emitting layer EM and the second electrode CE. The hole control layer may include a hole injection layer, a hole transport layer, or an electron blocking layer, and the electron control layer may include an electron injection layer, an electron transport layer, or a hole blocking layer.

The encapsulation layer TFE may be disposed on the display element layer DP-OLED and may encapsulate the light emitting elements OLED. The encapsulation layer TFE may include at least one layer of an inorganic layer and an organic layer. According to an embodiment, the encapsulation layer TFE may include inorganic layers and an organic layer disposed between the inorganic layers.

The inorganic layer of the encapsulation layer TFE may protect the light emitting elements OLED from moisture and/or oxygen. In an embodiment, for example, the inorganic layer may include at least one selected from aluminum oxide, titanium oxide, silicon oxide, silicon nitride, silicon oxynitride, zirconium oxide, and hafnium oxide, however, the inorganic layer should not be limited thereto or thereby.

The organic layer of the encapsulation layer TFE may protect the light emitting elements OLED from a foreign substance, such as dust particles. The organic layer may include an acrylic-based resin, however, the organic layer should not be limited thereto or thereby.

The first driving voltage ELVDD (refer to FIG. 5) and the second driving voltage ELVSS (refer to FIG. 5) may be respectively applied to the first electrode AE and the second electrode CE. Holes and electrons, which are injected into the light emitting layer EM, may be recombined with each other to generate excitons, and the light emitting elements OLED may emit a light when the excitons return to a ground state from an excited state. The light emitting elements OLED may emit the light in response to electrical signals applied thereto, and thus, the display panel DP may display the image through the display area DA (refer to FIG. 4).

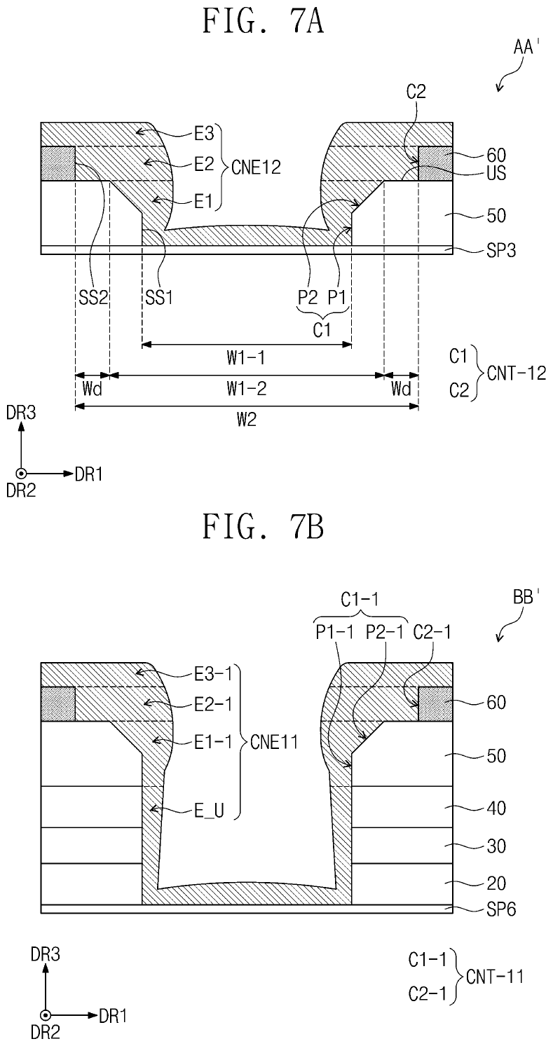

FIGS. 7A and 7B are cross-sectional views of some components of display element layers according to an embodiment of the disclosure. FIGS. 7A and 7B are enlarged views of areas AA′ and BB′ shown in FIG. 6, respectively.

Referring to FIG. 7A, in an embodiment, the first-second connection electrode CNE12 may be connected to the third semiconductor pattern SP3 via the contact hole CNT-12 defined through the fifth and sixth insulating layers 50 and 60. The first-second connection electrode CNE12 may be disposed on the sixth insulating layer 60 and in the contact hole CNT-12.

The contact hole CNT-12 may include a first contact hole C1 defined through the fifth insulating layer 50 and a second contact hole C2 defined through the sixth insulating layer 60. At least a portion of the third semiconductor pattern SP3 may be exposed through the first contact hole C1. At least a portion of an upper surface US of the fifth insulating layer 50 may be exposed through the second contact hole C2.

A first width of the first contact hole C1 may be less than a second width of the second contact hole C2. A first slope of the first contact hole C1 may be different from a second slope of the second contact hole C2. An imaginary center line of the first contact hole C1 may be substantially the same as an imaginary center line of the second contact hole C2, however, the first contact hole C1 and the second contact hole C2 may not be provided integrally with each other.

The first contact hole C1 may include a lower portion P1 adjacent to the third semiconductor pattern SP3 and having a first-first slope and an upper portion P2 adjacent to the second contact hole C2 and having a first-second slope.

The first slope of the first contact hole C1 may have a value that varies along the thickness direction DR3. In the first contact hole C1, the first-first slope of the lower portion P1 may be greater than the first-second slope of the upper portion P2. The first-first slope may be in an angle equal to or greater than about 85 degrees and equal to or less than about 95 degrees with respect to the upper surface US of the fifth insulating layer 50, and the first-second slope may be in an angle equal to or greater than about 60 degrees and equal to or less than about 80 degrees with respect to the upper surface US of the fifth insulating layer 50. In an embodiment, for example, the first-first slope may be in an angel of about 90 degrees with respect to the upper surface US of the fifth insulating layer 50. The second slope of the second contact hole C2 may be substantially uniform or constant along the thickness direction or the third direction DR3. In an embodiment, for example, the second slope of the second contact hole C2 may be in an angle of about 90 degrees with respect to the upper surface US of the fifth insulating layer 50.

The width of the first contact hole C1 in the first direction DR1 may have a value that varies along the thickness direction or the third direction DR3, that is, as moving in the thickness direction or the third direction DR3. A minimum value of the width of the first contact hole C1 may be equal to or greater than about 0.5 micrometers and equal to or less than about 2 micrometers. In the first contact hole C1, a first-first width W1-1 of the lower portion P1 may be less than a first-second width W1-2 of the upper portion P2. The first-first width W1 of the lower portion P1 may be substantially the same as the minimum value of the width of the first contact hole C1. That is, the first-first width W1 of the lower portion P1 may be equal to or greater than about 0.5 micrometers and equal to or less than about 2 micrometers. In an embodiment, for example, the first-first width W1 of the lower portion P1 may be equal to or greater than about 1 micrometers and equal to or less than about 1.8 micrometers. The width of the second contact hole C2 may have a value that is substantially uniform or constant along the thickness direction or the third direction DR3.

The first-second width W1-2 of the upper portion P2 of the first contact hole C1 may be less than the second width W2 of the second contact hole C2. That is, a maximum value of the width in the first direction DR1 of the first contact hole C1 may be less than the second width W2 of the second contact hole C2. A difference 2Wd in the first direction DR1 between the first-second width W1-2 and the second width W2 may be equal to or greater than about 0.2 micrometers. Here, the above-described difference 2Wd means the sum of two “Wd” shown in FIG. 7A. In an embodiment, for example, the difference 2Wd in the first direction DR1 between the first-second width W1-2 and the second width W2 may be equal to or greater than about 0.2 micrometers and equal to or less than about 3 micrometers. A ratio of the difference 2Wd between the first-second width W1-2 and the second width W2 to the first-first width W1-1, which is the minimum value of the width of the first contact hole C1, may be equal to or greater than about 0.2. In an embodiment, for example, the ratio of the difference 2Wd between the first-second width W1-2 and the second width W2 to the first-first width W1-1 may be equal to or greater than about 0.2 and equal to or less than about 3. However, the difference 2Wd between the first-second width W1-2 and the second width W2 should not be limited to the above numerical range, and the difference 2Wd between the first-second width W1-2 and the second width W2 may have various values depending on a width of the first-second connection electrode CNE12, a separation distance between the electrodes disposed on the fifth insulating layer 50, and an etching method when the display panel is manufactured.

The first-second connection electrode CNE12 may include a first electrode portion E1 disposed in the first contact hole C1, a second electrode portion E2 disposed in the second contact hole C2, and a third electrode portion E3 disposed on the sixth insulating layer 60. The first electrode portion E1 may be in contact with a first side surface SS1 of the fifth insulating layer 50, and the second electrode portion E2 may be in contact with a side surface of the sixth insulating layer 60. As the first-second width W1-2 of the first contact hole C1 is less than the second width W2 of the second contact hole C2, the second electrode portion E2 may be in contact with the upper surface US of the fifth insulating layer 50. The second electrode portion E2 may be entirely in contact with the upper surface US of the fifth insulating layer 50 exposed through the second contact hole C2.

A material included in the fifth insulating layer 50 may be different from a material included in the sixth insulating layer 60. In an embodiment, for example, the fifth insulating layer 50 may include silicon oxide, and the sixth insulating layer 60 may include silicon nitride. In such an embodiment, even though the sixth insulating layer 60 includes other materials rather than the silicon nitride, an upper surface of the sixth insulating layer 60, which is in contact with the first-second connection electrode CNE12, may include silicon nitride. Accordingly, when the display device according to an embodiment of the disclosure is manufactured, an etch rate of the fifth insulating layer 50 may be different from an etch rate of the sixth insulating layer 60. When the display device according to an embodiment of the disclosure is manufactured, a formation rate of the first contact hole C1 may be different from a formation rate of the second contact hole C2.

The first side surface SS1 of the fifth insulating layer 50 defining the first contact hole C1 may not be aligned with a second side surface SS2 of the sixth insulating layer 60 defining the second contact hole C2 in the thickness direction. The first side surface SS1 and the second side surface SS2 may not be aligned with each other and may be arranged in a staggered formation. Accordingly, the second electrode portion E2 may be in contact with the upper surface US of the fifth insulating layer 50 exposed through the second contact hole C2.

Referring to FIG. 7B, the first-first connection electrode CNE11 may be connected to the sixth semiconductor pattern SP6 via the contact hole CNT-11 defined through the second, third, fourth, fifth, and sixth insulating layers 20, 30, 40, 50, and 60. The first-first connection electrode CNE11 may be disposed on the second insulating layer 20 in the contact hole CNT-11. The second, third, and fourth insulating layers 20, 30, and 40 may include at least one selected from silicon oxide, silicon nitride, and silicon oxynitride or may have a structure in which a silicon oxide layer and a silicon nitride layer are alternately stacked.

The contact hole CNT-11 may include a first-first contact hole C1-1 defined through the fifth insulating layer 50 and a second-first contact hole C2-1 defined through the sixth insulating layer 60. Features of the first contact hole C1 and the second contact hole C2 with reference to FIG. 7A may be applied to the first-first contact hole C1-1 and the second-first contact hole C2-1 of FIG. 7B, respectively. The first-first connection electrode CNE11 may include a first-first electrode portion E1-1 disposed in the first-first contact hole C1-1 and a second-first electrode portion E2-1 disposed in the second-first contact hole C2-1. The first-first connection electrode CNE11 may include a third-first electrode portion E3-1 disposed on the sixth insulating layer 60 and a lower electrode portion E_U that is in contact with side surfaces of the second, third, and fourth insulating layers 20, 30, and 40. Features of the first electrode portion E1 and the second electrode portion E2 with reference to FIG. 7A may be applied to the first-first electrode portion E1-1 and the second-first electrode portion E2-1 of FIG. 7B, respectively.

FIGS. 7A and 7B show an embodiment having the structure of the contact holes CNT-11 and CNT-12 through which the third semiconductor pattern SP3 or the sixth semiconductor pattern SP6 is exposed, however, the disclosure should not be limited thereto or thereby. According to an embodiment, other contact holes through which other electrodes or electrode layers having conductivity are exposed may have a structure in which the first contact hole C1 and the second contact hole C2 are provided as described above.

In an embodiment of a display device configured or design to implement a high-resolution and a high-speed driving, the number of signal lines increases and the degree of integration of circuits increases. Accordingly, the width of the connection electrode and the width of the contact hole are minimized to configure a layout of the pixel within a limited pitch range of the pixel. However, when the width of the connection electrode and the width of the contact hole are reduced, due to a step coverage in the process, a shadow effect may occur or the connection electrode in contact with opposing ends of the contact hole may be cut.

In an embodiment of the display device including the fifth insulating layer and the sixth insulating layer that is disposed on the fifth insulating layer and in contact with the connection electrode, a side surface of the sixth insulating layer defining the second contact is disposed further away from the imaginary center line of the contact hole than a side surface of the fifth insulating layer defining the first contact hole. Accordingly, even when the width of the contact hole decreases, defects caused by the step coverage of the connection electrode may be reduced, and the occurrence of the cutting of the connection electrode, which is in contact with opposing ends of the contact hole, may be reduced since the connection electrode overlaps the upper surface of the fifth insulating layer. Accordingly, even though the number of signal lines increases and the degree of the circuit integration increases, the display device having high resolution, high speed driving, and high robustness characteristics may be implemented since the display device includes the second contact hole whose side is disposed further away from the imaginary center line than a side of the first contact hole is.

Hereinafter, an embodiment of a manufacturing method of the display device will be described in detail. In describing an embodiment of the method of manufacturing the display device, any repetitive detailed description of the same or elements as those described above will be omitted.

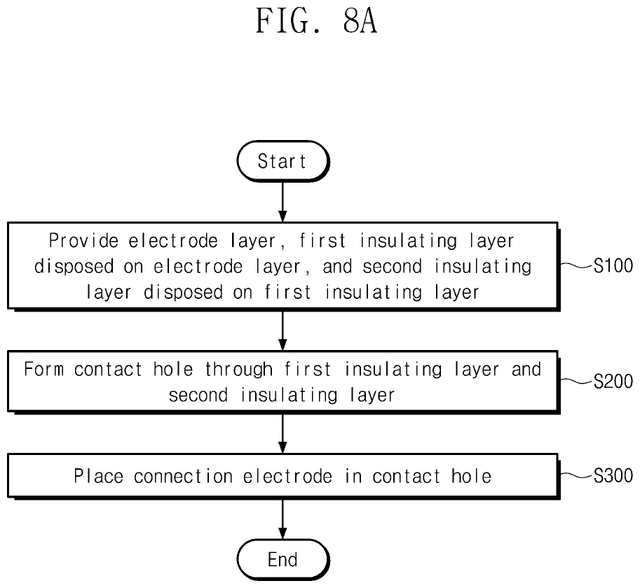

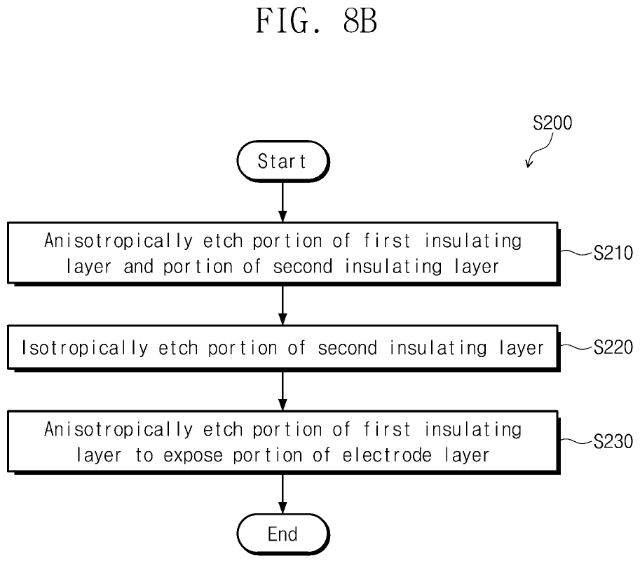

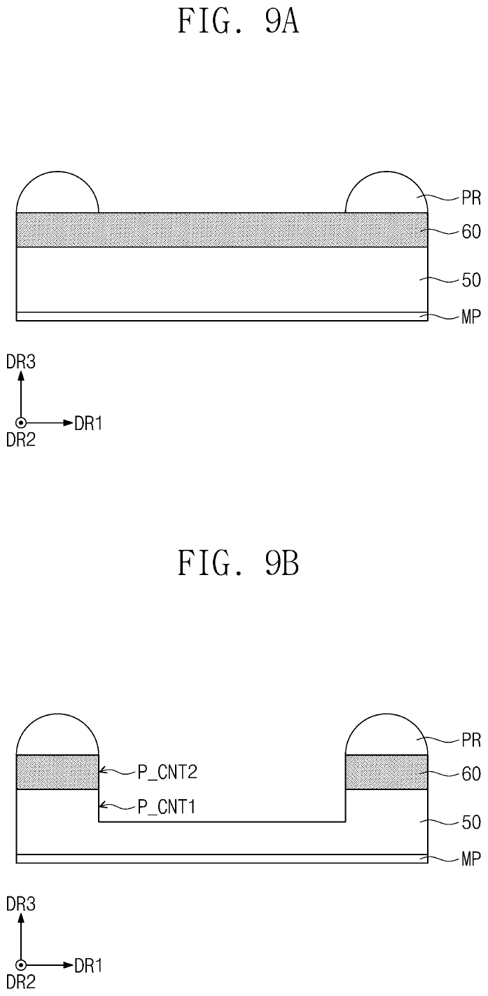

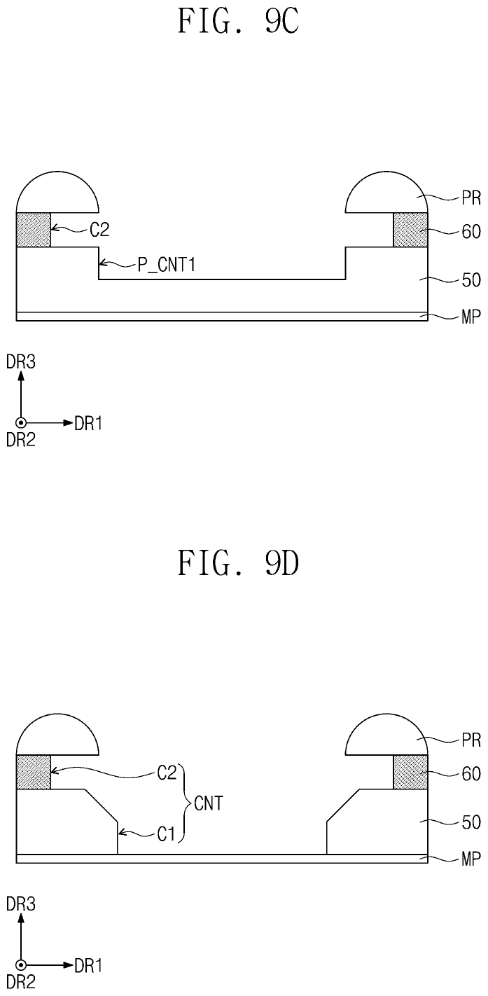

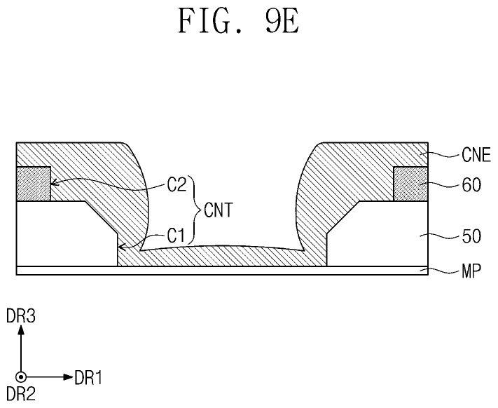

FIG. 8A is a flowchart illustrating the method of manufacturing the display device according to an embodiment of the disclosure. FIG. 8B is a flowchart illustrating a process of forming the contact hole of the manufacturing method of the display device according to an embodiment of the disclosure. FIGS. 9A to 9E are cross-sectional views illustrating the method of manufacturing the display device according to an embodiment of the disclosure.

Referring to FIG. 8A, an embodiment of the manufacturing method of the display device may include providing an electrode layer, a first insulating layer disposed on the electrode layer, and a second insulating layer disposed on the first insulating layer (S100), forming the contact hole through the first insulating layer and the second insulating layer (S200), and placing (or providing) the connection electrode in the contact hole (S300). Referring to FIG. 8B, in an embodiment, the forming of the contact hole through the first insulating layer and the second insulating layer (S200) may include anisotropically etching a portion of the first insulating layer and a portion of the second insulating layer (S210), isotropically etching a portion of second insulating layer (S220), and anisotropically etching a portion of the first insulating layer to expose a portion of the electrode layer (S230).

Referring to FIG. 9A, an embodiment of the manufacturing method of the display device may include the providing (or preparing) the electrode layer MP, the first insulating layer 50 (corresponding to the fifth insulating layer 50 described above) disposed on the electrode layer MP, and the second insulating layer 60 (corresponding to the sixth insulating layer 60 described above) disposed on the first insulating layer 50. In such an embodiment, the electrode layer MP may correspond to the third semiconductor pattern SP3 described with reference to FIG. 7A, the sixth semiconductor pattern SP6 described with reference to FIG. 7B, or other electrodes having conductivity.

Referring to FIGS. 9A to 9D, an embodiment of the manufacturing method of the display device may include the forming the contact hole CNT through the first insulating layer 50 and the second insulating layer 60. In such an embodiment, the contact hole CNT may correspond to the contact hole CNT-12 described with reference to FIG. 7A or the contact hole CNT-11 described with reference to FIG. 7B.

The forming of the contact hole CNT may include forming a photoresist pattern PR on the second insulating layer 60. Then, the forming of the contact hole CNT may include the anisotropic etching of the portion of the first insulating layer 50 and the portion of the second insulating layer 60. The anisotropic etching of the portion of the first insulating layer 50 and the portion of the second insulating layer 60 may include forming a first preliminary contact hole P_CNT1 through the first insulating layer 50 using a photoresist pattern PR as a mask and forming a second preliminary contact hole P_CNT2 through the second insulating layer 60 using the photoresist pattern PR as a mask. In the anisotropic etching of the portion of the first insulating layer 50 and the portion of the second insulating layer 60, the second insulating layer 60 may be entirely etched in the thickness direction DR3, but the first insulating layer 50 may be partially etched in the thickness direction DR3. The first preliminary contact hole P_CNT1 and the second preliminary contact hole P_CNT2, which are formed in the anisotropic etching of the portion of the first insulating layer 50 and the portion of the second insulating layer 60, may have substantially a same width as each other. The anisotropic etching of the portion of the first insulating layer 50 and the portion of the second insulating layer 60 may include a plasma etching process. Accordingly, each of the first preliminary contact hole P_CNT1 formed through the first insulating layer 50 and the second preliminary contact hole P_CNT2 formed through the second insulating layer 60 may have a slope in an angel of about 90 degrees with respect to an upper surface of the fifth insulating layer 50.

The forming of the contact hole CNT may include forming the second contact hole C2 defined through the second insulating layer 60. The forming of the second contact hole C2 may include increasing a width in the first direction DR1 of the second preliminary contact hole P_CNT2. The forming of the second contact hole C2 may include the isotropic etching of a portion of the second insulating layer 60. The isotropic etching of the portion of the second insulating layer 60 may include etching the portion of the second insulating layer 60, which is in contact with a lower surface of the photoresist pattern PR. The isotropic etching of the portion the second insulating layer 60 may include forming an undercut in a lower portion of the photoresist pattern PR. That is, the isotropic etching of the portion of the second insulating layer 60 may include etching the second insulating layer 60 in a direction parallel to the first direction DR1 or the second direction DR2, i.e., a horizontal direction. Accordingly, the second contact hole C2 having the width greater than the width in the first direction DR1 of the second preliminary contact hole P_CNT2 may be formed. The width in the first direction DR1 of the second contact hole C2 formed by isotropically etching the portion of the second insulating layer 60 may be greater than the width in the first direction DR1 of the first preliminary contact hole P_CNT1.

The isotropic etching of the second insulating layer 60 may include a plasma etching process. In an embodiment, for example, the first insulating layer 50 may include silicon oxide, and the second insulating layer 60 may include silicon nitride. In the isotropic etching of the second insulating layer 60, the etch rate of the second insulating layer 60 including silicon nitride may be greater than the etch rate of the first insulating layer 50 including silicon oxide. Accordingly, only the second insulating layer 60 may be isotropically etched in the horizontal directions with respect to the first and second directions DR1 and DR2 in the isotropic etching of the second insulating layer 60, and thus, the upper surface of the first insulating layer 50 may be exposed.

The forming of the contact hole CNT may include forming the first contact hole C1 through the first insulating layer 50. The forming of the first contact hole C1 may include increasing a thickness of the first preliminary contact hole P_CNT1. The forming of the first contact hole C1 may include the anisotropic etching of a portion of the first insulating layer 50. The forming of the first contact hole C1 may include etching the first insulating layer 50 in the third direction DR3 using the photoresist pattern PR as a mask. The forming of the first contact hole C1 may include etching the first insulating layer 50 to expose at least a portion of an upper surface of the electrode layer MP. The anisotropic etching of the portion of the first insulating layer 50 may include a plasma etching process.

Referring to FIG. 9E, an embodiment of the manufacturing method of the display device may include forming the connection electrode CNE in the contact hole CNT. In such an embodiment, the connection electrode CNE may correspond to the connection electrode CNE12 of FIG. 7A or the connection electrode CNE11 of FIG. 7B. The connection electrode CNE may be disposed in the contact hole CNT and on the second insulating layer 60.

An embodiment of the manufacturing method of the display device includes the anisotropic etching of the first insulating layer and the second insulating layer and the isotropic etching of the second insulating layer, and thus, the display device having characteristics, such as high resolution and high speed driving, may be manufactured. In such an embodiment, the manufacturing method of the display device includes the isotropic etching of the second insulating layer, such that the second contact hole whose side surface is disposed further away than the first contact hole may be formed, and thus, defects caused by the step coverage of the connection electrode disposed at the upper position and the electrical short of the connection electrode of the display device may be reduced. In such an embodiment, as the manufacturing method of the display device further includes the anisotropic etching of the first insulating layer and the second insulating layer, which is carried out before the isotropic etching process, the second contact hole may be deeply etched to allow the side surface thereof to be disposed further away than that of the first contact hole, such that the reliability of the display device may be improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a base layer;
a circuit layer disposed on the base layer; and
a light emitting element disposed on the circuit layer,
wherein the circuit layer comprises:
a first insulating layer disposed on the base layer, provided with a first contact hole defined therethrough, and comprising silicon nitride;
a second insulating layer disposed on the first insulating layer, provided with a second contact hole defined therethrough to correspond to the first contact hole, and comprising silicon oxide; and
a connection electrode disposed on the second insulating layer, wherein a portion of the connection electrode is disposed in the first and second contact holes,
wherein the connection electrode comprises a first electrode portion disposed in the first contact hole and a second electrode portion disposed in the second contact hole,
a minimum value of a width in one direction of the first contact hole is equal to or greater than about 0.5 micrometers and equal to or less than about 2 micrometers, and
a portion of the second electrode portion is in contact with an upper surface of the first insulating layer.

2. The display device of claim 1, wherein a maximum value of the width in the one direction of the first contact hole is less than a minimum value of a width in the one direction of the second contact hole.

3. The display device of claim 1, wherein
the first electrode portion is in contact with a first side surface of the first insulating layer,
the second electrode portion is in contact with a second side surface of the second insulating layer, and
the first side surface and the second side surface are arranged in a staggered form.

4. The display device of claim 1, wherein
the first contact hole comprises a lower portion adjacent to the base layer and having a first-first slope and an upper portion adjacent to the second insulating layer and having a first-second slope, and
the first-first slope is greater than the first-second slope.

5. The display device of claim 4, wherein
the first-first slope is in an angle equal to or greater than about 85 degrees and equal to or less than about 95 degrees with respect to the upper surface of the first insulating layer, and
the first-second slope is in an angle equal to or greater than about 60 degrees and equal to or less than about 80 degrees with respect to the upper surface of the first insulating layer.

6. The display device of claim 4, wherein a first-first width in the one direction of the lower portion is less than a first-second width in the one direction of the upper portion.

7. The display device of claim 6, wherein the first-first width in the one direction of the lower portion is equal to or greater than about 1 micrometer and equal to or less than about 1.8 micrometers.

8. The display device of claim 6, wherein
a width in the one direction of the second contact hole is uniform in a thickness direction, and
a difference between the first-second width in the one direction and the width of the second contact hole in the one direction is equal to or greater than about 0.2 micrometers.

9. The display device of claim 8, wherein a ratio of the difference between the first-second width and the width of the second contact hole to the first-first width in the one direction is equal to or greater than about 0.2.

10. The display device of claim 1, wherein the circuit layer further comprises:
a first organic layer disposed on the second insulating layer and provided with a first upper contact hole defined therethrough; and
an upper connection electrode disposed in the first upper contact hole and electrically connected to the connection electrode.

11. The display device of claim 10, wherein
the light emitting element comprises a first electrode, a light emitting layer disposed on the first electrode, and a second electrode disposed on the light emitting layer,
the circuit layer further comprises a second organic layer disposed on the first organic layer and provided with a second upper contact hole defined therethrough, and
a portion of the first electrode is disposed in the second upper contact hole and electrically connected to the upper connection electrode.

12. The display device of claim 1, wherein
the circuit layer further comprises a transistor disposed on the base layer,
the transistor comprises a semiconductor pattern disposed on the base layer and a gate electrode disposed on the first insulating layer,
at least a portion of an upper surface of the semiconductor pattern is exposed through the first contact hole, and
the connection electrode is electrically connected to the semiconductor pattern via the first and second contact holes.

13. The display device of claim 12, wherein
the circuit layer further comprises a lower insulating layer disposed on the base layer,
the semiconductor pattern is disposed on the lower insulating layer, and
the lower insulating layer comprises silicon oxide, silicon nitride or silicon oxynitride.

14. A display device comprising:
a base layer;
a circuit layer disposed on the base layer; and
a light emitting element disposed on the circuit layer,
wherein the circuit layer comprises:
a first insulating layer disposed on the base layer, provided with a first contact hole defined therethrough, and comprising silicon nitride;
a second insulating layer disposed on the first insulating layer, provided with a second contact hole defined therethrough to correspond to the first contact hole, and comprising silicon oxide; and
a connection electrode disposed on the second insulating layer,
wherein the first contact hole comprises a lower portion adjacent to the base layer and having a first-first slope and an upper portion adjacent to the second insulating layer and having a first-second slope,
the first-first slope is in an angle equal to or greater than about 85 degrees and equal to or less than about 95 degrees with respect to an upper surface of the first insulating layer, and
the first-second slope is in an angle equal to or greater than about 60 degrees and equal to or less than about 80 degrees with respect to the upper surface of the first insulating layer.

15. A method of manufacturing a display device, the method comprising:
providing an electrode layer, a first insulating layer comprising silicon nitride and disposed on the electrode layer, and a second insulating layer disposed on the first insulating layer and comprising silicon nitride;
forming a contact hole through the first insulating layer and the second insulating layer; and
providing a connection electrode in the contact hole,
wherein the forming the contact hole comprises:
anisotropically etching a portion of the first insulating layer and a portion of the second insulating layer;
isotropically etching a portion of the second insulating layer to expose an upper surface of the first insulating layer; and
anisotropically etching a portion of the first insulating layer to expose an upper surface of the electrode layer.

16. The method of claim 15, wherein the forming the contact hole further comprises forming a photoresist pattern on the second insulating layer before the anisotropically etching the portion of the first insulating layer and the portion of the second insulating layer.

17. The method of claim 15, wherein the anisotropically etching the portion of the first insulating layer and the portion of the second insulating layer comprises:
forming a first preliminary contact hole in the first insulating layer; and
forming a second preliminary contact hole through the second insulating layer,
wherein the first preliminary contact hole and the second preliminary contact hole have substantially a same slope as each other.

18. The method of claim 17, wherein the first preliminary contact hole is formed by etching only the portion of the first insulating layer in a thickness direction.

19. The method of claim 17, wherein the first preliminary contact hole and the second preliminary contact hole have substantially a same width on as each other.

20. The method of claim 16, wherein the isotropically etching the portion of the second insulating layer comprises forming an undercut in a lower portion of the photoresist pattern.
